(19) United States
(12) Patent Application Publication
(10) Pub. No.: US 2026/0002260 A1
(43) Pub. Date: Jan. 1, 2026

(54) MULTIZONE THERMALLY CONTROLLED SHOWERHEAD

(71) Applicant: ASM IP Holding B.V., Almere (NL)

(72) Inventors: Kyle Tantiwong, Scottsdale, AZ (US); Samer Banna, Phoenix, AZ (US)

(21) Appl. No.: 19/250,024

(22) Filed: Jun. 25, 2025

Related U.S. Application Data
(60) Provisional application No. 63/666,038, filed on Jun. 28, 2024.

(51) Int. Cl. C23C 16/455

(52) U.S. Cl. CPC C23C 16/45565; C23C 16/4557; C23C 16/45572

(57) ABSTRACT

A showerhead assembly for distributing a gas within a reaction chamber is provided. The showerhead assembly includes a top plate, a gas distribution plate, and a plurality of thermally controllable zones. The gas distribution plate is coupled to the top plate. The gas distribution plate also has a top surface facing the top plate and a bottom surface configured to face a substrate disposed within the reaction chamber. The plurality of thermally controllable zones are fabricated in at least one of the top plate and the gas distribution plate. Methods of controlling thermal profile of showerhead assemblies and methods of making showerhead assemblies are also described.

### CROSS REFERENCE TO RELATED APPLICATIONS

This application claims priority to and the benefits of U.S. Patent Provisional Application No. 63/666,038, filed on Jun. 28, 2024, the contents of which are incorporated herein by reference in its entirety.

### FIELD OF INVENTION

The present disclosure generally relates to fabricating semiconductor devices. Specifically, the present invention relates depositing material layers onto substrates during the fabrication of semiconductor devices.

### BACKGROUND OF THE DISCLOSURE

A typical semiconductor fabrication process module carries out a variety of processes to create functional devices (e.g., processors, memory, and power electronic devices). Conventional process modules utilize gas-phase chemistries to either etch or deposit a variety of materials using numerous methods including atomic layer deposition (ALD) and chemical vapor deposition (CVD). In many of these processes, a gas showerhead may be utilized to uniformly deliver chemistry to the wafer being processed. Due to complexity and high temperatures achieved during these processes (e.g., between about 300 degrees Celsius and about 500 degrees Celsius), the showerhead also typically has a thermal contribution to the wafer level reactions. In many of these processes, the showerhead is also subject to deposition of active species or etch by-product species. When this deposition becomes too thick, it can fall off and introduce yield-reducing defects, which then reduces process module maintenance intervals and over-all productivity. Process performance and process module uptime are both very important. In these cases, it may be desired to fully control the showerhead thermal profile to optimize over-all performance.

In many conventional cases, equipment makers make due with a center-to edge non-uniformity and instead use other process knobs to achieve the desired wafer uniformity. However, as the industry evolves, temperature regimes get more extreme and new chemistries get adopted, this method becomes more and more difficult. For certain chemistries and processes, unwanted deposition is hard to control and, in some cases, very hard to remove, even using well-known conventional in-situ cleaning methods. When center to edge non-uniformity is high, this deposition may start to flake prematurely, in which case controlling center to edge uniformity is optimal. Accordingly, there is a need in the art for a showerhead assembly that can be thermally controlled in varying regions of the showerhead assembly.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

A showerhead assembly for distributing a gas within a reaction chamber is provided. The showerhead assembly includes a top plate, a gas distribution plate, and a plurality of thermally controllable zones. The gas distribution plate is coupled to the top plate. The gas distribution plate also has a top surface facing the top plate and a bottom surface configured to face a substrate disposed within the reaction chamber. The plurality of thermally controllable zones are fabricated in at least one of the top plate and the gas distribution plate.

In addition to one or more of the features described above, or as an alternative, further examples of the showerhead assembly may include that each of the plurality of thermally controllable zones further includes at least one inlet configured to allow a cooling liquid to flow into a respective thermally controllable zone. Each of the plurality of thermally controllable zones may include at least one outlet configured to allow the cooling liquid to flow out of the respective thermally controllable zone.

In addition to one or more of the features described above, or as an alternative, further examples of the showerhead assembly may include that of each of the plurality of thermally controllable zones further includes comprises a second inlet configured to allow the cooling liquid to flow into the respective thermally controllable zone. Each of the plurality of thermally controllable zones may include a second outlet configured to allow the cooling liquid to flow out of the respective thermally controllable zone.

In addition to one or more of the features described above, or as an alternative, further examples of the showerhead assembly may include that the plurality of thermally controllable zone include three thermally controllable zones. Each of the three thermally controllable zones may be independently controllable.

In addition to one or more of the features described above, or as an alternative, further examples of the showerhead assembly may include that the plurality of thermally controllable zones include a heating component embedded in the gas distribution plate

In addition to one or more of the features described above, or as an alternative, further examples of the showerhead assembly may include that the heating component comprises a set of resistive heaters.

In addition to one or more of the features described above, or as an alternative, further examples of the showerhead assembly may include that the plurality of thermally controllable zones include a first set of resistive heaters. The first set of resistive heaters may define a first zone. The plurality of thermally controllable zones may include a second set of resistive heaters. The second set of resistive heaters may define a second zone. The plurality of thermally controllable zones may include a third set of resistive heaters. The third set of resistive heaters may define a third zone.

In addition to one or more of the features described above, or as an alternative, further examples of the showerhead assembly may include that the first zone, the second zone and the third zone are concentric to the showerhead assembly.

In addition to one or more of the features described above, or as an alternative, further examples of the showerhead assembly may include a plurality of conduction rods. The plurality of conduction rods may be coupled to the top surface of the gas distribution plate. A cooling liquid may be flowed through the top plate of the showerhead assembly.

In addition to one or more of the features described above, or as an alternative, further examples of the showerhead assembly may include that the radial conduction rods are cylindrical.

In addition to one or more of the features described above, or as an alternative, further examples of the showerhead assembly that the plurality of radial conduction rods may be concentric to the gas distribution plate.

In addition to one or more of the features described above, or as an alternative, further examples of the showerhead assembly may include that the radial conduction rods are composed of aluminum.

In addition to one or more of the features described above, or as an alternative, further examples of the showerhead assembly may include that the top plate is composed of aluminum. The gas distribution plate may be composed of aluminum.

In addition to one or more of the features described above, or as an alternative, further examples of the showerhead assembly may include that the plurality of radial conduction rods are composed of a material that is both thermally conductive and an electrically insulative.

In addition to one or more of the features described above, or as an alternative, further examples of the showerhead assembly may include that the plurality of radial conduction rods are formed from a ceramic material. In such examples the ceramic material may be silicon nitride (Si₃N₄), aluminum nitride (AlN), beryllium oxide (BeO), silicon carbide (SiC), and boron nitride (BN).

In addition to one or more of the features described above, or as an alternative, further examples of the showerhead assembly may include a set of radial heaters. The set of radial heaters may be embedded in the top plate.

In addition to one or more of the features described above, or as an alternative, further examples of the showerhead assembly may include one or more radial heaters. The one or more radial heaters may include a first set of radial heaters. The first set of radial heaters may define a first zone. The one or more radial heaters may include a second set of radial heaters. The second set of radial heaters may define a second zone. The one or more radial heaters may include a third set of radial heaters. The third set of radial heaters may define a third zone.

A method of controlling a thermal profile of a showerhead assembly is provided. The method includes flowing a cooling fluid into one or more zones fabricated in the showerhead assembly; monitoring temperature of the showerhead assembly in the one or more zones; and adjusting at least one of (a) the flow of the cooling fluid in the one or more zones, and (b) temperature in the one or more zones.

A method of controlling a thermal profile of a showerhead assembly is provided. The method includes providing a top plate. The method further includes flowing a cooling fluid into one or more zones fabricated in the showerhead assembly, monitoring temperature of the showerhead assembly in the one or more zones; and adjusting at least one of (a) the flow of the cooling fluid in the one or more zones, and (b) the temperature in the one or more zones.

In addition to one or more of the features described above, or as an alternative, further examples of the method of controlling the thermal profile of the showerhead assembly may include that adjusting the flow of the cooling fluid includes using a flow meter.

In addition to one or more of the features described above, or as an alternative, further examples of the method of controlling the thermal profile of the showerhead assembly may include that adjusting temperature includes controlling heating components embedded in the showerhead assembly.

In addition to one or more of the features described above, or as an alternative, further examples of the method of controlling the thermal profile of the showerhead assembly may include that the showerhead assembly includes a plurality of zones. In such examples the at least one of (a) adjusting at least one the flow of the cooling fluid in the one or more zones and (b) adjusting temperature in the one or more zones may further include controlling each of the plurality of zones independently of the other zones.

A method of manufacturing a showerhead assembly is provided. The method includes providing a top plate. The method further includes providing a gas distribution plate coupled to the top plate. The gas distribution plate has a top surface facing the top plate and a bottom surface facing a substrate. Finally, the method includes providing a plurality of thermally controllable zones fabricated in at least one of the top plate or the gas distribution plate.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 illustrates a cross section of an exemplary showerhead assembly in accordance with embodiments described herein;

FIG. 2 illustrates a top view of one embodiment of a thermally controllable gas distribution plate that may be used in the showerhead assembly of FIG. 1 in accordance with embodiments described herein;

FIG. 3 illustrates a top view of one embodiment of a thermally controllable gas distribution plate that may be used in the showerhead assembly of FIG. 1 in accordance with embodiments described herein;

FIG. 4 illustrates a cross section of an exemplary showerhead assembly in accordance with embodiments described herein;

FIG. 5 illustrate a top view of gas distribution plate that may be used in the showerhead assembly of FIG. 4 in accordance with embodiments described herein; and

FIG. 6 illustrates a flow diagram of a method of manufacturing a thermally controlled showerhead assembly of FIG. 1 in accordance with embodiments described herein.

FIG. 7 illustrates a flow diagram of a method of controlling a thermal profile of a showerhead assembly of FIG. 1 in accordance with embodiments described herein.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be in semiconductor processing systems employed to fabricate semiconductor devices, such as in semiconductor processing systems employed to deposit material layers using atomic layer deposition (ALD) and/or chemical vapor deposition (CVD) techniques use during the fabrication of semiconductor devices like memory, logic, and power electronic devices, though the present disclosure is not limited to any particular semiconductor processing technique or to the fabrication of any particular type of semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

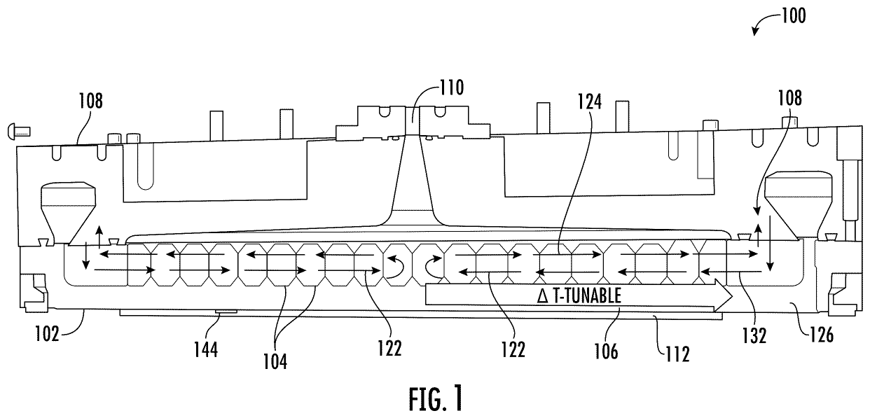

FIG. 1 illustrates an exemplary showerhead assembly 100 in accordance with a non-limiting example embodiment of the disclosure. Showerhead assembly 100 comprises a gas distribution assembly 102, including a plurality of apertures 104, and a chamber or region 106. Showerhead assembly 100 may also include a top plate (also described herein as gas control plate) 108 and a gas inlet 110. In exemplary embodiments, the top plate 108 and the gas distribution assembly/plate 102 is composed of aluminum. It should be noted that the gas distribution assembly 102 illustrated in FIG. 1 is shown in a simplified block form and does not illustrate the detailed embodiments of the disclosure to be described herein.

During operation, one or more purge gases and/or one or more precursors and/or reactants flow through gas inlet 110, to chamber 106, and through apertures 104 toward a substrate 112. In the illustrated example, the direction of the flow of the gas in gas inlet 110 and apertures 104 is substantially vertical, e.g., substantially (e.g., with five (5) degrees of being) perpendicular to a surface of substrate 112.

Due to complexities, high temperatures are achieved during deposition of many of these processes. A pedestal supporting substrate 112 is substantially heated during most of these processes and provides thermal energy to substrate 112. The thermal energy radiated from this pedestal is transferred to showerhead assembly 100 and impacts thermal uniformity of showerhead assembly 100, specifically, gas distribution plate 102. By controlling the heat transferred from the pedestal to gas distribution plate 102, a desired thermal profile of the showerhead assembly 100 may be generated. That is, as shown in FIG. 1, tunable zones may be fabricated in showerhead assembly 100 for desired heating or cooling in different sections of the showerhead assembly 100.

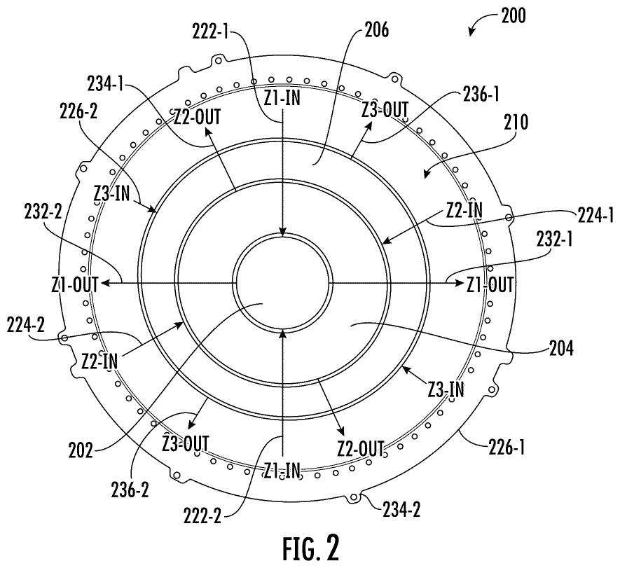

FIG. 2 illustrates a top view of one embodiment of a thermally controllable gas distribution plate 200. Gas distribution plate 200 is included within a gas distribution assembly 102 (shown in FIG. 1). As shown in FIG. 2, gas distribution plate 200 includes multiple tunable zones (202, 204, 206). In the example shown in FIG. 2, gas distribution plate 200 includes three tunable zones fabricated into the gas distribution plate 200. In exemplary embodiments, tunable zones 202, 204 and 206 are cooling zones. Each of the tunable zones further include at least one inlet and one outlet, for example at least one coolant inlet and at least one coolant outlet.

As shown in FIG. 2, a first cooling zone 202 includes at least one inlet 222-1. In exemplary embodiments, first cooling zone 202 may further include a second inlet 222-2. First cooling zone 202 further includes at least one outlet 232-1 and in exemplary embodiments, includes a second outlet 232-2. The first cooling zone 202 may be defined in a center section of gas distribution plate 200. Accordingly, when zone 202 requires cooling, zone 202 may be cooled by opening one or both inlets 222-1 and 222-2 to allow a cooling liquid to flow into cooling zone 202. After the showerhead assembly cools to a desired temperature, one or both outlets 232-1 and 232-2 may be opened to allow the cooling liquid to flow out from zone 202.

As also shown in FIG. 2, a second cooling zone 204 includes at least one inlet 224-1. In exemplary embodiments, second cooling zone 204 may further include a second inlet 224-2. Second cooling zone 204 further includes at least one outlet 234-1 and in exemplary embodiments, includes a second outlet 234-2. The second cooling zone 204 may be defined in a donut shape surrounding first zone 202. Accordingly, when zone 204 requires cooling, zone 204 may be cooled by opening one or both inlets 224-1 and 224-2 to allow a cooling liquid to flow into cooling zone 204. After the showerhead assembly cools to a desired temperature, one or both outlets 234-1 and 234-2 may be opened to allow the cooling liquid to flow out from zone 204.

As further shown in FIG. 2, a third cooling zone 206 includes at least one inlet 226-1. In exemplary embodiments, third cooling zone 206 may further include a second inlet 226-2. Third cooling zone 206 further includes at least one outlet 236-1 and in exemplary embodiments, includes a third outlet 236-2. The third cooling zone 206 may be defined in a donut shape surrounding second zone 204. Accordingly, when zone 206 requires cooling, zone 206 may be cooled by opening one or both inlets 226-1 and 226-2 to allow a cooling liquid to flow into cooling zone 206. After the showerhead assembly cools to a desired temperature, one or both outlets 236-1 and 236-2 may be opened to allow the cooling liquid to flow out from zone 206.

Accordingly, cooling liquid may be flowed through inlets 222-1 and 222-2 and further sealed within first zone 202. Similarly, cooling liquid may be flowed through inlets 224-1 and 224-2 and further sealed within second zone 204. And likewise, cooling liquid may be flowed through inlets 226-1 and 226-2 and further sealed within third zone 206. In exemplary embodiments, showerhead assembly 100 shown in FIG. 1 further includes a pedestal (not shown) that can support substrate 112. After processing, the pedestal is heated to a high temperature (between about 300 degrees Celsius and about 500 degrees Celsius). Thus, the cooling liquid flowed through the gas distribution plate 200 can be directly heated by radiation of the pedestal. The cooling liquid flowing through each zone can be controlled through various inlets (222, 224 and 226) and outlets (232, 234, and 236). A flow meter may be used to control the flow of liquid in different zones. By controlling the flow of liquid through different zones, a thermal profile of the showerhead may be created. For example, in some processes, the thermal profile of the showerhead may need to be uniform. Some processes may require edge roll-off. Yet other processes may require center dip in temperature. Accordingly, by controlling the flow of the cooling liquid in different zones, a tunable option is available for process steps before or after use.

Turning back briefly to FIG. 1, the path of inlets (222, 224 and 226) and outlets (232, 234 and 236) through gas distribution assembly 102 is shown in FIG. 1. Path 122 represents the flow of cooling liquid into one or more zones of gas distribution assembly 102 and path 124 represents the flow of cooling liquid out of the one more zones of gas distribution assembly 102. Accordingly, the cooling liquid circulates through the gas distribution assembly 102 in a controlled manner by controlling the inlets and outlets.

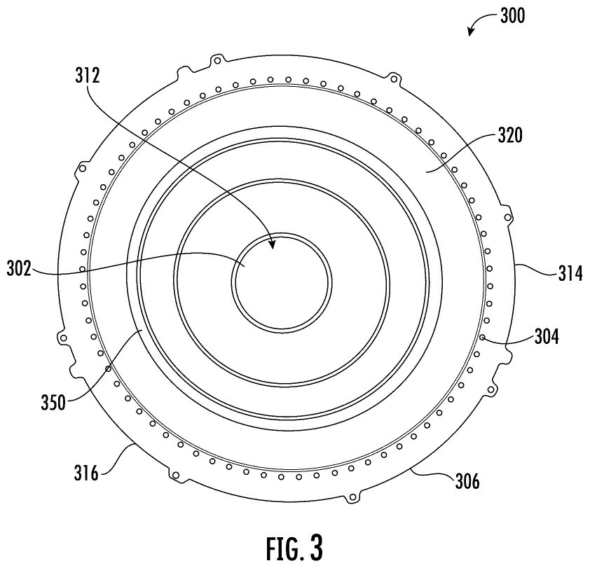

FIG. 3 illustrates a top view of one thermally controllable gas distribution plate 300. Gas distribution plate 300 is included within a gas distribution assembly 102 (shown in FIG. 1). As shown in FIG. 3, gas distribution plate 300 includes multiple tunable zones (302, 304, 306). In the example embodiment shown in FIG. 3, cooling liquid 350 is flowed through gas distribution plate 300. That is, uniform cooling is provided to cool the entire showerhead. In exemplary embodiments, this cooling liquid is consistently circulating through the gas distribution plate 300.

Temperature controllable components may be further embedded in concentric zones to create a radiality tunable profile. In exemplary embodiments, heaters are embedded in the gas distribution plate 300. In further exemplary embodiments, these heaters may be a series of resistive heaters. As shown in FIG. 3, multiple zones (302, 304, 306) are defined by a set of heaters embedded in the gas distribution plate 300. In the example shown in FIG. 3, three concentric zones are defined by a set of heaters.

A first zone 302 is defined by a first set of heaters 312. In exemplary embodiments, the first zone 302 may be defined in a center section of gas distribution plate 300. A second zone 304 is defined by a second set of heaters 314. In exemplary embodiments, the second zone 304 may be defined around the center zone 302 of gas distribution plate 300. A third zone 306 is defined by a third set of heaters 316 in a donut shape. In exemplary embodiments, the third zone 306 may be defined around the second zone 304 in a donut shape. Each of the zones 302, 304 and 306 are controllable by controlling the heaters embedded in the region defining the respective zone.

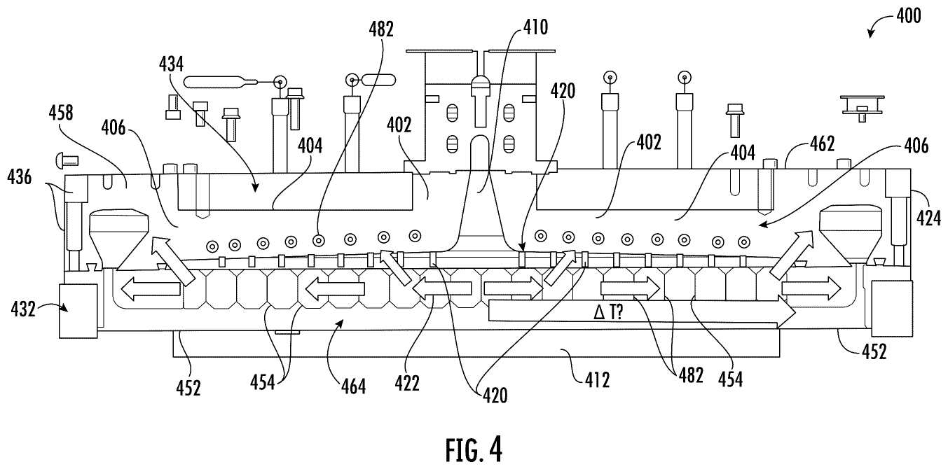

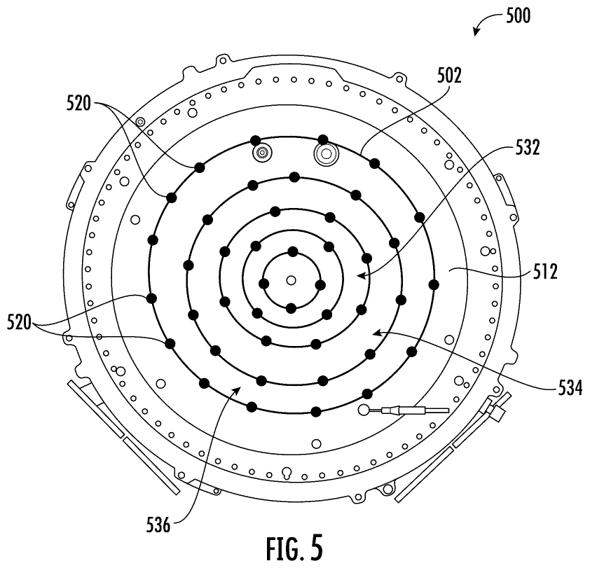

FIGS. 4 and 5 illustrate an exemplary thermally controllable showerhead assembly 400 in accordance with a non-limiting example embodiment of the disclosure. Thermally controllable showerhead assembly 400 functions in a manner similar to showerhead assembly 100 (shown in FIG. 1). Further, like showerhead assembly 100 of FIG. 1, showerhead assembly 400 comprises a gas distribution plate 452, including a plurality of apertures 454, and a chamber or region 456. The gas distribution plate 452 includes a top side 462 and a bottom side 464 that is opposite of top side 462. Top side 462 is proximate to a top plate 458 included in showerhead assembly 400. Bottom side 464 is proximate to a substrate 412. Showerhead assembly 400 further includes a gas inlet 410. During operation, one or more purge gases and/or one or more precursors and/or reactants flow through gas inlet 410 and through apertures 454 toward a substrate 412.

Showerhead assembly 400 further includes a plurality of radial conduction rods 420. In exemplary embodiments, the plurality of radial conduction rods 420 is in direct contact with gas distribution plate 452. In further exemplary embodiments, the plurality of radial conduction rods 420 is directly connected to the gas distribution plate 452 at a top side 462. In exemplary embodiments, conduction rods 420 are cylindrical in shape. In exemplary embodiments, conduction rods 420 may be composed of aluminum. In exemplary embodiments, conduction rods 420 may be formed from (e.g., consist of or consist essentially of) a material that is both thermally conductive and electrically insulative. Non-limiting examples of materials that are both suitably thermally conductive and electrically include certain ceramic materials, such as silicon nitride (Si₃N₄), aluminum nitride (AlN), beryllium oxide (BeO), silicon carbide (SiC), and boron nitride (BN). Advantageously, forming the conductions rods 420 from a material that is both thermally conductive and electrically insulative enables electrically separating gas distribution plate 452 from other components, for example from top plate 458.

In exemplary embodiments, cooling fluid flows through top plate 458. In further exemplary embodiments, this cooling fluid flows uniformly through top plate 458. As described herein, after processing, a pedestal supporting substrate 412 may be heated to a high temperature (between about 300 degrees Celsius and about 500 degrees Celsius). Consequently, gas distribution plate 452 may also have high temperatures after processing. This heat may be absorbed by the cooling fluid via the plurality of radial conduction rods 420.

In exemplary embodiments, showerhead assembly 400 may include an additional cooling component 434. For example, cooling component 434 may be a cooling liquid reservoir that controls the flow of cooling liquid to top plate 458. In exemplary embodiment, additional cooling component may be incorporated directly into the showerhead (such as cooling component 432).

Further, in exemplary embodiments, showerhead assembly 400 includes radial heaters 482 embedded in top plate 458. The radial heaters can be embedded to define multiple thermal zones (402, 404, 406). As shown in FIG. 4, radial heaters 482 may be controllable by zones. For example, radial heaters 482-1 are embedded in a first thermal zone 402, radial heaters 482-2 are embedded in a second thermal zone 404, and radial heaters 482-3 are embedded in a third thermal zone 406. Accordingly, the flow rate and/or radial heaters 482 can be used to control the desired amount of heating and cooling of different zones in the showerhead assembly 400 and provide a tunable radial profile.

FIG. 5 illustrates a top view of a gas distribution plate 500. Gas distribution plate 500 is similar to the gas distribution plate 452 shown in FIG. 4. As shown in FIG. 5, radial conduction rods 520 are arranged in concentric manner on distribution plate 500. The radial conduction rods 520 are directly connected to top surface 512 of distribution plate 500. These radial conduction rods 520 are also in constant touch (e.g., intimate mechanical contact) with a cooling liquid that flows external to the gas distribution plate 500. This cooling liquid can thus absorb the thermal energy impacting gas distribution plate 500.

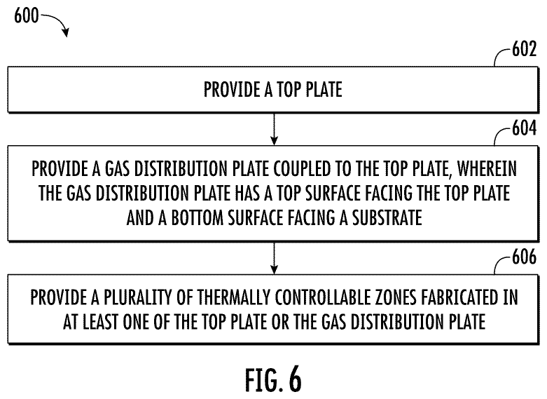

FIG. 6 illustrates a method 600 of manufacturing a showerhead assembly, such as showerhead assembly 100. Method 600 includes providing a top plate, such as top plate 108 (shown in FIG. 1) or 458 (shown in FIG. 4), as shown with box 602. Method 600 further includes providing a gas distribution plate, such as gas distribution plate 102, 200, 300, 452, coupled to the top plate. The gas distribution plate has a top surface facing the top plate and a bottom surface facing a substrate, such as substrate 112, 412, as shown with box 604. Method 600 further includes providing a plurality of thermally controllable zones fabricated in at least one of the top plate or the gas distribution plate, as shown with box 606.

In exemplary embodiments of method 600, providing a plurality of thermally controllable zones further includes providing a first inlet, such as inlet 222 configured to flow a cooling liquid into a first zone, such as zone 202. Method 600 further includes providing a first outlet, such as outlet 232, configured to flow the cooling liquid out of the first zone. Method 600 further includes providing a second inlet, such as inlet 224, configured to flow the cooling liquid into a second zone, such as zone 204. Method 600 further includes providing a second outlet, such as outlet 234 configured to flow the cooling liquid out of the second zone.

In exemplary embodiments of method 600, providing a plurality of thermally controllable zones includes providing a first set of resistive heaters, such as heaters 312, that define a first zone, such as zone 302. Method 600 further includes providing a second set of resistive heaters, such as heaters 314, that define a second zone 304.

In exemplary embodiments of method 600, providing a plurality of thermally controllable zones includes providing a plurality of radially conduction rods, such as conduction rods 420, that are directly in contact with the gas distribution plate, such as plate 452. Method 600 further includes providing cooling liquid through the top plate, such as top plate 458. Method 600 further includes providing a set of radial heaters, such as heaters 482, embedded in the top plate.

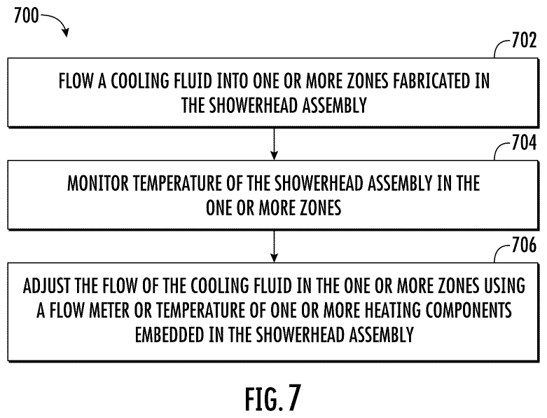

FIG. 7 illustrates a method 700 of controlling a thermal profile of a showerhead assembly. Method 700 includes flowing a cooling fluid into one or more zones (such as the zones illustrated in FIGS. 2-4) fabricated in the showerhead assembly, as shown with box 702. Method 700 further includes monitoring temperature of the showerhead assembly in the one or more zones, as shown with box 704. Method 700 further includes adjusting the flow of the cooling fluid in the one or more zones using a flow meter or temperature of one or more heating components embedded in the showerhead assembly, as shown with box 706.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A showerhead assembly for distributing a gas within a reaction chamber, comprising:
a top plate;
a gas distribution plate coupled to the top plate, the gas distribution plate having a top surface facing the top plate and a bottom surface configured to face a substrate disposed within the reaction chamber; and
a plurality of thermally controllable zones fabricated in at least one of the top plate or the gas distribution plate.

2. The showerhead assembly of claim 1, wherein each of the plurality of thermally controllable zones comprises:
at least one inlet configured to allow a cooling liquid to flow into a respective thermally controllable zone; and
at least one outlet configured to allow the cooling liquid to flow out of the respective thermally controllable zone.

3. The showerhead assembly of claim 2, wherein each of the plurality of thermally controllable zones comprises:
a second inlet configured to allow the cooling liquid to flow into the respective thermally controllable zone; and
a second outlet configured to allow the cooling liquid to flow out of the respective thermally controllable zone.

4. The showerhead assembly of claim 1, wherein the plurality of thermally controllable zones comprises three thermally controllable zones, and wherein each of the three zones are independently controllable.

5. The showerhead assembly of claim 1, wherein the plurality of thermally controllable zones comprises a heating component embedded in the gas distribution plate.

6. The showerhead assembly of claim 5, wherein the heating component comprises a set of resistive heaters.

7. The showerhead assembly of claim 6, wherein the plurality of thermally controllable zone comprises a first set of resistive heaters wherein the first set defines a first zone, a second set of resistive heaters wherein the second set defines a second zone, and a third set of resistive heaters wherein the third set defines a third zone, and wherein each of the first zone, second zone and third zone are independently controllable.

8. The showerhead assembly of claim 7, wherein the first zone, the second zone and the third zone are concentric to the showerhead assembly.

9. The showerhead assembly of claim 1, further comprising:
a plurality of radial conduction rods coupled to the top surface of the gas distribution plate; and
a cooling liquid flowed through the top plate.

10. The showerhead assembly of claim 9, wherein the radial conduction rods are composed of aluminum.

11. The showerhead assembly of claim 9, wherein the radial conduction rods are composed of a material that is both thermally conductive and an electrically insulative.

12. The showerhead assembly of claim 11, wherein the top plate and the gas distribution plate are composed of aluminum.

13. The showerhead assembly of claim 9, further comprising a set of radial heaters embedded in the top plate.

14. The showerhead assembly of claim 13, wherein the plurality of thermally controllable zone comprises a first set of radial heaters wherein the first set defines a first zone, a second set of radial heaters wherein the second set defines a second zone, and a third set of radial heaters wherein the third set defines a third zone, and wherein each of the first zone, second zone and third zone are independently controllable.

15. The showerhead assembly of claim 9, wherein the radial conduction rods are concentric to the gas distribution plate.

16. A method of controlling a thermal profile of a showerhead assembly, comprising:
flowing a cooling fluid into one or more zones fabricated in the showerhead assembly;
monitoring temperature of the showerhead assembly in the one or more zones; and
adjusting at least one of (a) the flow of the cooling fluid in the one or more zones, and (b) the temperature in the one or more zones.

17. The method of claim 16, wherein adjusting the flow of the cooling fluid comprises using a flow meter.

18. The method of claim 16, wherein adjusting the temperature comprises controlling heating components embedded in the showerhead assembly.

19. The method of claim 16, wherein the showerhead assembly comprises a plurality of zones, and wherein adjusting at least one of the flow of the cooling fluid in the one or more zones or the temperature in the one or more zones further comprises controlling each of the plurality of zones independently of the other zones.

20. A method of manufacturing a showerhead assembly, the method comprising:
providing a top plate;
providing a gas distribution plate coupled to the top plate, wherein the gas distribution plate has a top surface facing the top plate and a bottom surface facing a substrate; and
providing a plurality of thermally controllable zones fabricated in at least one of the top plate or the gas distribution plate. at least one inlet configured to allow a cooling liquid to flow into a respective thermally controllable zone; and
at least one outlet configured to allow the cooling liquid to flow out of the respective thermally controllable zone.
